(19) United States
(12) Patent Application Publication
(10) Pub. No.: US 2020/0144451 A1
(43) Pub. Date: May 7, 2020

(54) NITRIDE SEMICONDUCTOR CRYSTAL AND METHOD OF FABRICATING THE SAME

(71) Applicant: MEIJO UNIVERSITY, Nagoya-shi (JP)

(72) Inventors: Tetsuya TAKEUCHI, Nagoya-shi (JP); Tomoyuki SUZUKI, Nagoya-shi (JP); Hiroki SASAJIMA, Nagoya-shi (JP); Motoaki IWAYA, Nagoya-shi (JP); Isamu AKASAKI, Nagoya-shi (JP)

(73) Assignee: MEIJO UNIVERSITY, Nagoya-shi (JP)

(21) Appl. No.: 16/738,946

(22) Filed: Jan. 9, 2020

Related U.S. Application Data
(62) Division of application No. 14/773,045, filed on Sep. 4, 2015.

(30) Foreign Application Priority Data
Mar. 7, 2013 (JP) 2013-044869

(51) Int. Cl. H01L 33/32; C23C 16/30; H01L 21/02; C30B 25/02; C30B 29/40; H01L 33/00

(52) U.S. Cl. CPC H01L 33/32; C23C 16/303; H01L 21/0262; H01L 33/0075; H01L 21/0254; C30B 25/02; C30B 29/403; H01L 21/02549

(57) ABSTRACT

Fabricating a high-quality nitride semiconductor crystal at a lower temperature. A nitride semiconductor crystal is fabricated by supplying onto a substrate (105) a group III element and/or a compound thereof, a nitrogen element and/or a compound thereof and an Sb element and/or a compound thereof, all of which serve as materials, and thereby vapor-growing at least one layer of nitride semiconductor film (104). A supply ratio of the Sb element to the nitrogen element in a growth process of the at least one layer of the nitride semiconductor film (104) is set to not less than 0.004.

### TECHNICAL FIELD

The present invention relates to a nitride semiconductor crystal and a method of fabricating the same.

### BACKGROUND ART

A nitride semiconductor such as gallium nitride (GaN) is a direct transition (direct bandgap) semiconductor and has a wide bandgap ranging from 0.7 to 6.2 eV. Accordingly, the nitride semiconductor has widely been used for fabrication of a high-efficient blue light-emitting diode (LED) and the like. Although various methods of growing a nitride semiconductor crystal have been known, a metal organic chemical vapor deposition (MOCVD) is widely used. In the MOCVD, the composition of crystal to be fabricated is easy to control, and the MOCVD is superior in mass productivity. The undermentioned patent document 1 discloses a technique of steepening and flattening an interface between a p-type nitride semiconductor and a p-side electrode using a surfactant.

### PRIOR ART DOCUMENT

### Patent Documents

Patent Document 1: Japanese Patent Application Publication No. JP-A-2009-277931

### SUMMARY OF THE INVENTION

### Problem to be Overcome by the Invention

However, a deposition temperature of the nitride semiconductor crystal in a general method of vapor phase epitaxial growth is about 1,000° C., which value is relatively higher. Accordingly, the fabrication cost is high and reduction in size of a depositing apparatus is difficult. Further, when film deposition of the nitride semiconductor crystal is performed under the condition of temperature lower than 1,000° C., there arises a problem that the flatness of crystal surface and an interface between crystals deteriorate to a large degree. Furthermore, there is also a problem that a p-type GaN fabricated by deposition at a low temperature does not present a sufficient p-type conductivity due to the above-mentioned deterioration in the crystallinity.

The present invention was made in view of the foregoing circumstances and an object of the invention is to fabricate a high-quality nitride semiconductor crystal under the condition of lower temperatures.

### Means for Overcoming the Problem

A nitride semiconductor crystal of the first invention is fabricated by supplying onto a substrate a group III element and/or a compound thereof, a nitrogen element and/or a compound thereof and an Sb element and/or a compound thereof, all of which serve as materials, and thereby vapor-growing at least one layer of nitride semiconductor film. A supply ratio of the Sb element to the nitrogen element in a growth process of the at least one layer of the nitride semiconductor film is set to not less than 0.004.

A nitride semiconductor crystal of the second invention comprises 0.04% or more of Sb.

Since these nitride semiconductor crystals have high surface flatness and high quality, the crystals are useful for use with semiconductor devices such as a light-emitting/-receiving device and an electronic device.

In a method of fabricating a nitride semiconductor crystal, of the third invention, at least one layer of nitride semiconductor film is vapor-grown by supplying onto a substrate a group III element and/or a compound thereof, a nitrogen element and/or a compound thereof and an Sb element and/or a compound thereof, all of which serve as materials. In the method, a supply ratio of the Sb element to the nitrogen element in a growth process of the at least one layer of the nitride semiconductor film is set to not less than 0.004.

In this method of fabricating the nitride semiconductor crystal, the supply ratio of the Sb element to the nitrogen element is set to not less than 0.004 with the result that a nitride semiconductor crystal having a high-quality nitride semiconductor film can be fabricated at a lower temperature. Further, in this fabricating method, occurrence of phase separation due to heat can be suppressed when a mixed crystal containing the nitride semiconductor crystal is fabricated. Consequently, the composition control of the nitride semiconductor crystal is rendered easier. Further, this fabricating method can prevent characteristic degradation of the base film due to heat when the nitride semiconductor films are sequentially stacked and grown.

### BRIEF DESCRIPTION OF THE DRAWINGS

FIG. 1 is a cross-sectional view of the nitride semiconductor crystal according to embodiment 1;

FIG. 2 is an SEM image of the surface of low-temperature deposited GaN layer, (a) showing a sample not supplied with Sb and (b) showing a sample supplied with Sb;

FIG. 3 is an AFM image of the surface of low-temperature deposited GaN layer, (a) showing a sample not supplied with Sb and (b) showing a sample supplied with Sb;

FIG. 4 is a graph showing PL spectrum of the low-temperature deposited GaN layer, (a) showing a sample deposited at 950° C. and (b) showing a sample deposited at 850° C.;

FIG. 5 is a graph showing results of X-ray diffraction measurement of the low-temperature deposited GaN layer, (a) showing a sample deposited at 950° C. and (b) showing a sample deposited at 850° C.;

FIG. 6 is a graph showing an SIMS profile of Sb concentration with respect to a depthwise direction of laminated film of low-temperature deposited GaN layer;

FIG. 7 is a cross-sectional view of AlInN/GaN heterojunction structure according to embodiment 2; and

FIG. 8 is a cross-sectional view of nitride semiconductor light-emitting diode element structure according to embodiment 3.

### MODE FOR CARRYING OUT THE INVENTION

Preferred embodiments of the invention will be described.

The nitride semiconductor crystals of the first invention and the second invention may be doped with an acceptor impurity. In this case, since the nitride semiconductor crystal contains 0.04% or more Sb, upper ends of valence bands of the nitride semiconductor are raised, and with this, energy difference between the upper ends of valence bands and an acceptor impurity state becomes small. Accordingly, a high hole concentration is obtainable.

In the method of fabricating the nitride semiconductor crystal of the third invention, the nitride semiconductor film may be deposited at a deposition temperature which is equal to or lower than a deposition temperature of a base film. In this case, the deposition of the nitride semiconductor film can prevent the base film from deterioration by heat. This can improve design/trial fabrication freedom of the device.

Embodiments 1 to 4 will be described with reference to the drawings, which embodiments embody the nitride semiconductor crystals of the first invention and the second invention and the method of fabricating a nitride semiconductor crystal of the third invention.

### Embodiment 1

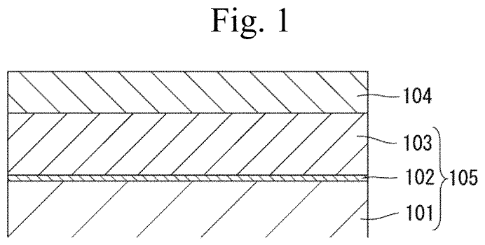

A sample of nitride semiconductor crystal having a structure as shown in FIG. 1 is fabricated by a metal organic chemical vapor deposition (MOCVD) in the following procedure. Firstly, a sapphire substrate 101 having a 1-cm square c-plane is set in a reacting furnace of a metal organic chemical vapor deposition (MOCVD) apparatus. Subsequently, a thermal cleaning treatment is carried out for a surface of the sapphire substrate 101 by increasing a temperature of the surface while hydrogen is caused to flow into the reaction furnace. Next, the temperature of the substrate (deposition temperature) is set to 630° C., and a low-temperature buffer layer 102 of gallium nitrogen (GaN) is grown by 20 nm on the sapphire substrate 101 by supplying into the reacting furnace hydrogen serving as a carrier gas, ammonia (nitrogen compound) and trimethylgallium (TMGa; and group III compound) both serving as materials. Subsequently, the substrate temperature is increased to 1130° C., and a non-doped base GaN layer (i-GaN; and base film) 103 is grown by 3 μm by supplying a similar carrier gas and the aforementioned materials. A substrate 105 includes the sapphire substrate 101 and the base GaN layer 103.

Further, the substrate temperature is decreased to a desired temperature, and a low-temperature deposited GaN layer 104 is grown (deposited) by 2 μm on the base GaN layer 103 while triethylantimony (TESb) serving as an Sb compound is supplied in addition to hydrogen serving as the carrier gas, and TMGa and ammonia both serving as the materials. In the deposition of the low-temperature deposited GaN layer 104A, a gas flow rate of the ammonia is set to 27 mmol/min, a gas flow rate of the TMGa is set to 28 μmol/min, and a gas flow rate of the TESb is set to 98 μmol/min. A gas flow ratio (supply ratio) of ammonia to TMGa is approximately 1,000. The ratio will hereinafter be referred to as “N/Ga”. Further, a gas flow ratio of TESb to ammonia is approximately 0.004. The ratio will hereinafter be referred to as “Sb/N”.

Samples S0, S1 and S2 are prepared by forming low-temperature deposited GaN layers 104 at three levels of substrate temperature, that is, at 750° C., 850° C. and 950° C. with TESb being supplied. Further, samples C0, C1 and C2 serving as comparative examples are prepared by forming low-temperature deposited GaN 104 under the same conditions as the samples S0, S1 and S2, without supply of TESb. The samples S0, S1 and S2 will hereinafter be referred to as Sb-supplied samples, and the samples C0, C1 and C2 will hereinafter be referred to as Sb-non-supplied samples.

The following describes evaluation results of crystalline of Sb-supplied samples S0, S1 and S2 and Sb-non-supplied samples C0, C1 and C2.

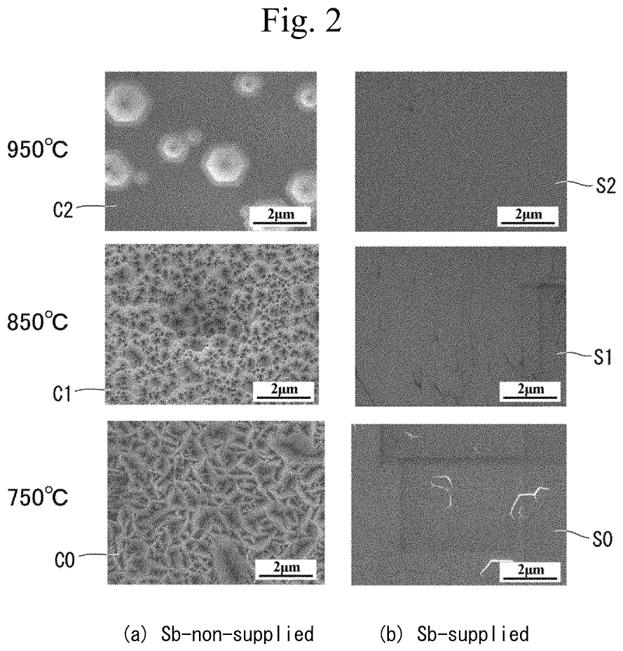

FIG. 2 shows surface scanning electron microscope (surface SEM) images of samples S0 and C0 formed at 750° C., samples S1 and C1 formed at 850° C. and samples S2 and C2 formed at 950° C. FIG. 2(a) shows surface SEM images of Sb-non-supplied samples C0, C1 and C2. FIG. 2(b) shows surface SEM images of Sb-supplied samples S0, S1 and S2. Regarding Sb-non-supplied sample C2, a plurality of inverted hexagonal pyramid pits can be observed on the crystal surface. Further, regarding each one of Sb-non-supplied samples C0 and C1 formed at lower temperatures than the sample C2, an entire surface is covered with pits. This suggests that the crystallinity and surface flatness become worse as the substrate temperature is decreased. However, regarding each one of the Sb-supplied samples S0, S1 and S2, no pits are observed on the surface, so that desirable surface flatness is obtained.

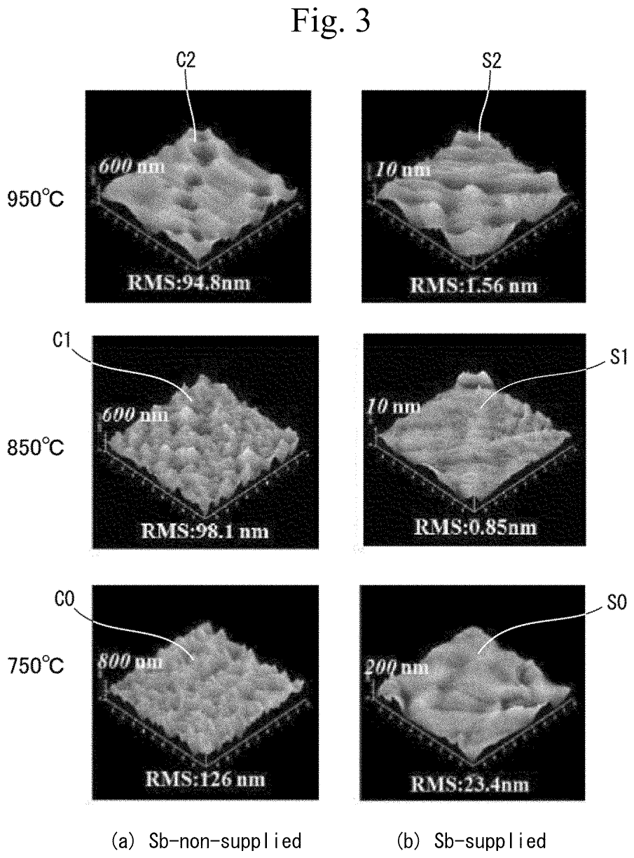

In order that more microscopic surface flatness may be observed, mapping measurement of difference in the surface level by an atomic force microscope (AFM) regarding samples S0 and C0 deposited at 750° C., samples S1 and C1 deposited at 850° C. and samples S2 and C2 deposited at 950° C. FIG. 3-(a) shows AFM images of Sb-non-supplied samples C0, C1 and C2. FIG. 3-(b) shows AFM images of Sb-supplied samples S0, S1 and S2. RMS (root mean square) values of surface roughness of Sb-non-supplied samples C0, C1 and C2 are approximately 100 nm. Regarding Sb-supplied samples S0, S1 and S2, however, RMS values of surface roughness are improved to a large degree as compared with Sb-non-supplied samples C0, C1 and C2. Samples S2, S1 and S0 have specific surface roughness RMS values of 1.56 nm, 0.85 nm and 23 nm, respectively. The surface roughness RMS values of samples S1 and S2 fall within a value corresponding to approximately one atomic layer. These values compare well with RMS values of surface roughness of a GaN layer deposited under the conventional condition of deposition temperature of not less than 1,000° C. Accordingly, it can be confirmed that each of Sb-supplied samples S0, S1 and S2 microscopically has an exceedingly favorable surface flatness.

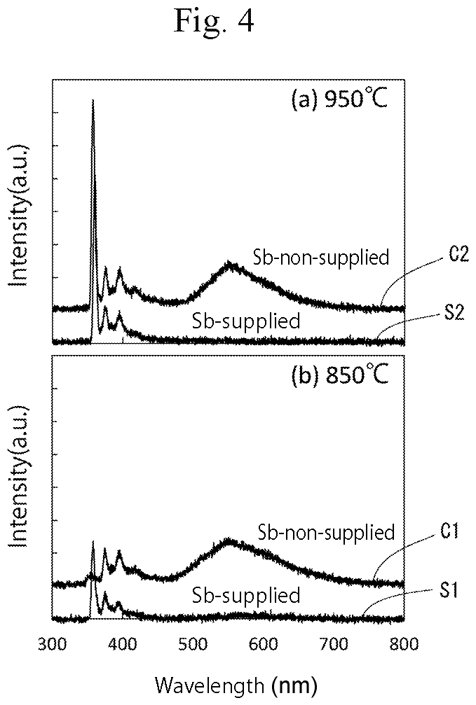

Next, in order that optical characteristics of the low-temperature deposited GaN layer 104 may be evaluated, photoluminescence (PL) spectra of samples S1 and C1 deposited at 850° C. and samples S2 and C2 deposited at 950° C. were measured under the condition of a low temperature of 20 Kelvin (K). FIGS. 4(a) and 4(b) are graphs showing PL detection intensities relative to emission wavelength. FIG. 4(a) shows PL spectra of samples S2 and C2 deposited at 950° C. FIG. 4 (b) shows PL spectra of samples S1 and C1 deposited at 850° C. When attention is drawn to samples S2 and C2 deposited at 950° C., a steep emission peak based on band edge of the GaN monocrystal can be confirmed in the vicinity of wavelength of 360 nm in each one of samples S2 and C2. However, broad emission (yellow luminescence) resulting from Ga vacancy as crystal defect is observed in a wavelength band of 500 to 700 nm regarding Sb-non-supplied sample C2. On the other hand, no yellow luminescence is observed regarding Sb-supplied sample S2. More specifically, it is suggested that an amount of Ga vacancy is smaller in Sb-supplied sample S2 than in Sb-non-supplied sample C2 and the crystallinity is better. Further, when attention is drawn to the samples S1 and C1 deposited at 850° C., the steep emission peak based on band edge cannot be almost observed in sample C1 although can be observed in sample C2. Further, an emission peak based on band edge can be observed regarding sample S1 although the emission intensity is inferior as compared with sample S2. More specifically, it is suggested that the Sb-supplied samples S1 and S2 are superior also from the standpoint of optical characteristics. As a result, further improvements in the crystallinity and optical characteristics of low-temperature deposited GaN layer 104 can be expected by increasing the gas flow ratio Sb/N to or above 0.004.

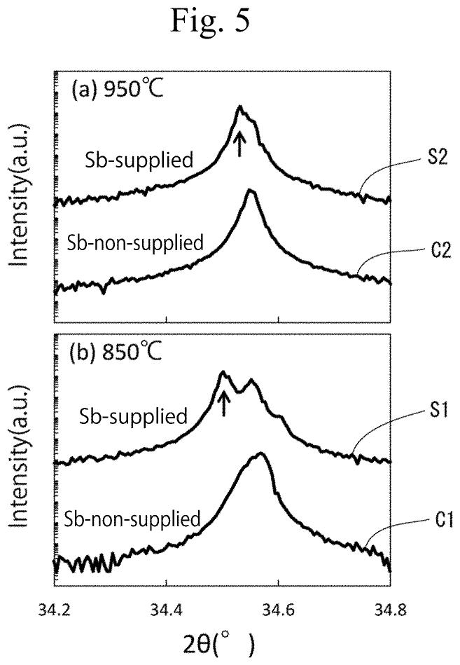

Next, in order that an intake amount of Sb in the low-temperature deposited GaN layer 104 may be evaluated, x-ray diffraction measurement (XRD; and 2θ/ω scan) of the Sb-supplied samples S1 and S2 was carried out. FIGS. 5(a) and 5(b) are graphs each having a horizontal axis denoting a rotation angle (2θ/ω) and a vertical axis denoting a detecting intensity. Peaks resulting from a Miller Index of (0002) of GaN are measured in each of the samples S2 and S1 deposited at 950° C. and 850° C. respectively. Furthermore, peaks as shown by arrows are confirmed at lower angle sides of samples S2 and S1. The peaks are considered to result from intake of Sb. The low-temperature deposited GaN layer 104 contains Sb ranging from 0.2% to 0.4%, as estimated from the peak positions.

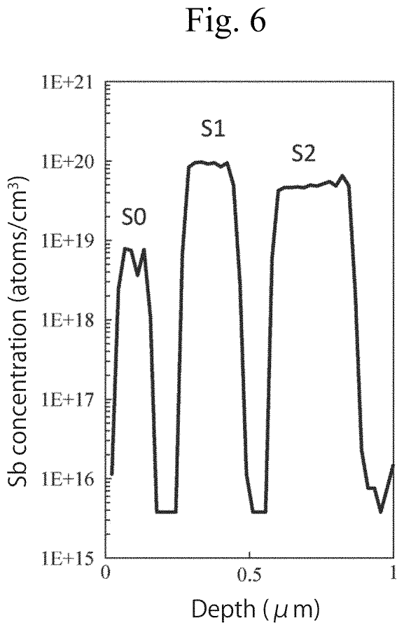

In order that an intake amount of Sb in the low-temperature deposited GaN layer 104 may be evaluated in more detail, low-temperature GaN layers fabricated under the same growth conditions as of Sb-supplied samples S0, S1 and S2 are stacked into the same samples. Sb concentrations relative to the depthwise direction of the stacked films were measured by a secondary ion mass spectrometry (SIMS). FIG. 6 is a graph showing Sb concentrations relative to the depthwise direction. When Sb compositions in the crystals are calculated from the results of FIG. 6, the samples S0, S1 and S2 contain 0.04% Sb, 0.4% Sb and 0.2% Sb respectively.

When the Sb compositions measured by the above SIMS and the results of surface roughness RMS values by the AFM measurement as shown in FIG. 3 are generalized, the surface flatness of the low-temperature deposited GaN layer 104 is improved by increasing the Sb composition in the layer 104 to or above 0.04%. More preferably, by increasing the Sb composition to or above 0.2%, the surface flatness and optical characteristics of the layer 104 are improved to a level such that the layer 104 compares well with a GaN layer deposited under a higher temperature condition.

According to the above-described embodiment, in the fabrication of the nitride semiconductor crystal (GaN) by the MOCVD, the gas flow ratio of TESb to ammonia is set to the value of not less than 0.004, whereby the deposition temperature (growth temperature) can be rendered lower, down to about 750° C. This can reduce the manufacturing costs and render the deposition equipment smaller in size.

Further, the low-temperature deposited GaN layer 104 formed at the low temperature with Sb being supplied is superior in the crystallinity, surface flatness and optical characteristics as compared with the low-temperature deposited GaN layer 104 deposited at the low temperature without supply of Sb. Accordingly, the low-temperature deposited GaN layer 104 is useful for use as semiconductor devices such as a light-emitting/-receiving device, an electronic device and the like.

Further, the low-temperature deposited GaN layer 104 in which the Sb composition in the crystal is not less than 0.04% superior in the surface flatness even though deposited under the low temperature condition. Still further, the band edge emission can be confirmed regarding the low-temperature deposited GaN layer 104 in which the Sb composition in the crystal is not less than 0.2%, and the low-temperature deposited GaN layer 104 has good optical characteristics. Accordingly, the low-temperature deposited GaN layer 104 is particularly useful for use as a light-emitting/-receiving device.

Indium (In) as a group III element is hardly taken in under high temperature conditions such as 1000° C. as in the prior art, and there is a possibility of phase separation, with the result that a nitride semiconductor crystal containing fine In is hard to obtain. In the embodiment, however, a fine GaN layer 104 can be formed under the condition of the growth temperature of not more than 800° C. at or below which In can sufficiently be taken in. As a result, a high-quality nitride semiconductor mixed crystal can be obtained while the In composition in the crystal is increased. Consequently, the composition control of the nitride semiconductor mixed crystal is rendered easier, and a device is more easily manufactured which emits/receives longer-wavelength side light by forming an active layer with high In composition which has been heretofore hard to manufacture.

Further, there is a case where a device to be manufactured is exposed to a high-temperature environment of a deposition process (growth process) thereby to be deteriorated in the characteristics thereof. A thermal budget can be reduced by totally lowering the growth temperature of the nitride semiconductor crystal as in the embodiment. This can improve a design/trial manufacture freedom in the manufacture of devices.

### Embodiment 2

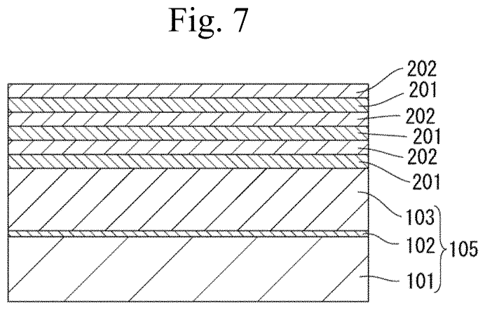

An AlInN/GaN heterojunction structure as shown in FIG. 7 is fabricated by the MOCVD in the following procedure. Since a fabrication process up to the fabrication of the substrate 105 and the fabrication conditions are common to embodiments 1 and 2, the description of the fabricating process and conditions will be eliminated.

Firstly, the substrate temperature is reduced to 850° C., and nitrogen serving as a carrier gas, trimetylindium (TMIn, a group III compound) as a material, trimetylaluminum (TMAl, a group III compound), ammonia and TESb as the Sb compound are supplied into the reaction furnace, so that the AlInN layer 201 is grown on the base GaN layer 103 by 40 nm. A deposition rate is set to 0.2 μm/h which value is relatively higher. Further, a gas flow ratio is set so that the ratio Sb/N becomes about 0.004 in the same manner as in embodiment 1. The In composition of the deposited AlIn layer 201 is set to 0.17 and is substantially lattice-matched to the GaN crystal. Thereafter, the TESb is supplied in addition to the carrier gas and TMGa as a material gas while the substrate temperature is maintained at 850° C., so that a GaN layer 202 is grown on the AlInN layer 201 by 40 nm. A cycle of the deposition of the AInN layer 201 and the GaN layer 202 is repeated three times, with the result that a three-pair stacked AlInN/GaN heterojunction structure is fabricated.

It is known that the crystallinity of the obtained AlInN layer 201 are deteriorated to a large degree by speeding up the deposition rate to or above 0.2 μm/h in the deposition process of the AlInN layer 201. According to embodiment 2, a high quality crystal of the AlInN layer 201 can be obtained by supplying the TESb even under the high-speed deposition condition. Accordingly, the fabrication time and costs can be reduced since the deposition rate can be sped up in the fabrication of the AlInN/GaN heterojunction structure, too, as well as the effect that a high-quality crystal can be obtained as described in embodiment 1.

Further, the thermal budget can be reduced by fabricating the AlInN/GaN heterojunction structure under the condition of temperature lower than the deposition temperature of the base GaN layer 103 serving as the base film, with the result that the design/trial manufacture freedom can be improved in the manufacture of a device structure.

Further, 40 to 60 pairs of AlInN/GaN heterojunction structures are required to be stacked when a multi-layer film reflecting mirror necessary for a surface-emitting laser is fabricated. As a result, the effect of reducing the fabrication time and costs can be rendered exceedingly great.

### Embodiment 3

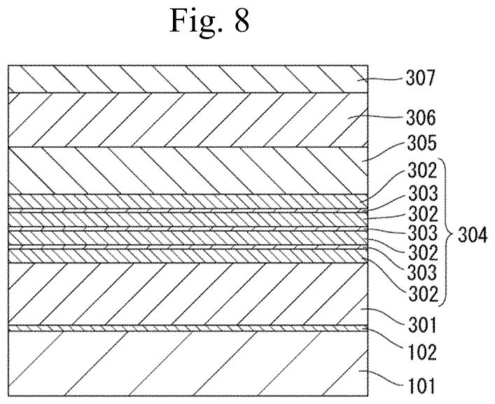

A nitride semiconductor light-emitting diode element structure as shown in FIG. 8 is fabricated by the MOCVD in the following procedure. Since a fabrication process up to the fabrication of the low-temperature buffer layer 102 and the fabrication conditions are common to embodiments 1 and 3, the description of the common process and conditions will be eliminated. The gas flow ratio Sb/N in the following deposition conditions is set to about 0.004 in all cases.

Firstly, the substrate temperature is increased to 1080° C., and hydrogen as a carrier gas, TMGa and ammonia as materials, silane (SiH₄) as an impurity material gas are supplied into the reaction furnace, so that an n-type GaN layer (n-GaN) 301 is grown on the low-temperature buffer layer 102 by 3 μm. The n-GaN 301 is doped with Si at a concentration of 3×10¹⁸/cm³.

Subsequently, the substrate temperature is reduced to 850° C., and nitrogen as a carrier gas, the TMIn and TMGa and ammonia as materials, and the TESb as an Sb compound are supplied into the reaction furnace, so that a GaN barrier layer 302 and a GaInN quantum well layer 303 are stacked and grown on the n-type GaN layer 301 in turn. The GaN barrier layer 302 has a film thickness of 10 nm, and the GaInN quantum well layer 303 has a film thickness of 2.5 rm. Further, the GaInN quantum well layer 303 contains 0.15% In. Four GaN barrier layers 302 and three GaInN quantum well layers 303 are deposited alternately, so that a GaN/GaInN active layer 304 as shown in FIG. 8 is formed.

Further, the substrate temperature is increased to 980° C., and hydrogen serving as a carrier gas, the TMGa and TMAl and ammonia as materials, the TESb as an Sb compound and cyclopentadienyl magnesium (CP₂Mg) as an impurity material gas are supplied into the reaction furnace, so that a p-type AlGaN electron block layer (p-AlGaN) 305 is grown on the GaN/GaInN active layer 304. The p-type AlGaN electron block layer 305 has a film thickness of 25 nm and contains 0.15% Al. The p-type AlGaN electron block layer 305 is doped with Mg (an accepter impurity) at a concentration of 3×10¹⁹/cm³.

Further, the substrate temperature is reduced to 850° C., and hydrogen as a carrier gas, the TMGa and ammonia as materials, the TESb as an Sb compound and the CP₂Mg as an impurity material gas are supplied into the reaction furnace, so that a p-type GaN layer (p-GaN) 306 and a contact-forming p-type GaN contact layer (p++−GaN) 307 are stacked and grown on the p-type AlGaN electron block layer (p-AlGaN) 305 in turn. The p-type GaN layer 306 has a film thickness of 60 nm, and the p-type GaN contact layer 307 has a film thickness of 10 nm. Further, the p-type GaN layer 306 is doped with Mg at a concentration of 3×10¹⁹/cm³. The p-type GaN contact layer 307 is doped with Mg at a concentration of 1×10²⁰/cm³.

According to embodiment 3, a high-quality crystal can also be obtained at a lower temperature by supplying TESb during the deposition with respect to the n-type GaN layer 301 doped with Si. Further, high-quality crystals can also be obtained at a lower temperature with respect to the p-type GaN layer 306, the p-type GaN contact layer 307 and the p-type AlGaN electron block layer 305 all of which are doped with Mg, respectively. Further, the GaInN quantum well layer 303 can also be deposited under the condition of low temperature of 770° C. at which In can sufficiently be taken in.

Further, the deposition temperature of the p-type AlGaN electron block layer 305 deposited on the GaN/GaInN active layer 304 can be set to 980° C. which value is lower than in the prior art. Accordingly, since the thermal budget for the GaN/GaInN active layer 304 can also be reduced, the design/trial manufacture in the manufacture of devices can be improved.

Further, when p-type layers are deposited, the Sb is taken in so that GaN and AlGaN each contain not less than 0.2% Sb. Accordingly, upper ends of valence bands of GaN and AlGaN are raised with the result that energy difference between GaN and AlGaN, and an acceptor impurity (Mg) state becomes small. Accordingly, activation energy thereof is reduced and accordingly, high-concentration holes are formable. This improves an injection efficiency of the holes into GaN/GaInN active layer 304 and suppresses electron overflow, thereby improving light-emitting characteristics of a light-emitting diode.

### Embodiment 4

The substrate temperature of GaInN quantum well layer 303 is set to 750° C. in the nitride semiconductor light-emitting diode element structure similar in embodiment 3, so that the composition of In can be increased to or above 0.3. According to embodiment 4, emission from the GaN/GaInN active layer 304 can be shifted to the long-wavelength side, so that a green-color and in addition, yellow-color light-emitting diodes become fabricatable.

According to the invention, a group III element and/or a compound thereof serving as a material, a nitrogen element and/or a compound thereof and an Sb element and/or a compound thereof are supplied onto the substrate 105, so that at least one layer of nitride semiconductor film 104 is vapor-grown on the substrate 105 to be fabricated into a nitride semiconductor crystal. The supply ratio of the Sb element to the nitrogen element in this case is set to 0.004 or above, whereby the high-quality nitride semiconductor crystal can be fabricated at a lower temperature. Further, since the obtained nitride semiconductor crystal has a high quality, the nitride semiconductor crystal is useful in the application to semiconductor devices such as a light-emitting/-receiving device and an electronic device.

The invention should not be limited to embodiments 1 to 4 as described above with reference to the drawings. For example, the following embodiments are within the technical scope of the invention.

(1) Although the sapphire substrate is used in the foregoing embodiments, silicon (Si), zinc oxide (ZnO), silicon carbide (SiC), gallium arsenic (GaAs), gallium nitride (GaN), aluminum nitride (AlN) or the like may be used, instead. Further, there is no limitation to pleomorphism (polytype) of crystal.

(2) Although the metal organic chemical vapor deposition (MOCVD) is employed as a technique for growing the nitride semiconductor crystal in the foregoing embodiments, a hydride vapor-phase epitaxy (HVPE) or another vapor-phase epitaxial method may be applied. Further, a molecular beam epitaxy (MBE), a sputtering method, a laser ablation method or the like may be applied.

(3) Although trimethylgallium (TMGa), trimethylaluminum (TMAl) and trimethylindium (TMIn) are used as materials in the foregoing embodiments, triethylgallium (TEGa), triethylindium (TEIn), triethylaluminum (TEA1) or the like may be used, instead.

(4) Although triethylantimony (TESb) is used as the Sb element and the Sb compound in the foregoing embodiments, trimethylantimony (TMSb) or trisdimethylaminoantimony (TDMASb) may be used, instead.

(5) Although hydrogen or nitrogen is used as the carrier gas in the foregoing embodiments, another active gas or another inert gas such as argon or a mixture of these gases may be used, instead.

(6) Although gallium nitride (GaN) is used as the low-temperature buffer layer in the foregoing embodiments, aluminum nitride (AlN), indium nitride (InN), boron nitride (BN) or the like may be used, instead.

(7) Although the base film having the film thickness of 3 μm is deposited before the forming of the nitride semiconductor film in the foregoing embodiments, the base film may not be deposited.

(8) Although the c-axis-oriented nitride semiconductor crystal is fabricated on the c-plane sapphire substrate in the foregoing embodiments, the nitride semiconductor crystal may be m-axis oriented or a-axis oriented.

(9) Although Si and Mg are used as dopants of n-type GaN and p-type GaN in the foregoing embodiments, Ge, Zn, Be or the like may be used, instead.

### EXPLANATION OF REFERENCE SYMBOLS

103 . . . base GaN layer (base film); 104, 201, 202, 302, 303, 305, 306, 307 . . . nitride semiconductor film (104 . . . low-temperature deposited GaN layer, 201 . . . AlInN layer, 202 . . . GaN layer, 302 . . . GaN barrier layer, 303 . . . GaInN quantum well layer, 305 . . . p-type AlGaN electron block layer, 306 . . . p-type GaN layer, 307 . . . p-type GaN contact layer); and 105 . . . substrate.

1.-6. (canceled)

7. A method of fabricating a nitride semiconductor crystal, comprising:
supplying a group III element, a nitrogen element, and an Sb element into a reaction furnace of a metal organic chemical vapor deposition apparatus, all the elements serving as materials; and
depositing a GaN crystal onto a sapphire substrate disposed in the reaction furnace, a temperature of the sapphire substrate being set in a range of 850° C. to 950° C., Sb being taken into the GaN crystal.

8. The method according to claim 1,
wherein the GaN crystal has an Sb composition ranging from 0.2% to 0.4% and has a root mean square surface roughness ranging from 0.85 nm to 1.56 nm.
